(19) United States
(12) Patent Application Publication
(10) Pub. No.: US 2025/0022981 A1
(43) Pub. Date: Jan. 16, 2025

(54) APPARATUS, SYSTEM, AND METHOD FOR INCREASING CARRIER CONFINEMENT IN LIGHT-EMITTING DEVICES

(71) Applicant: Meta Platforms Technologies, LLC, Menlo Park, CA (US)

(72) Inventors: Julia D'Rozario, Sammamish, WA (US); David Massoubre, Rathcormac (IE); Francois Gérard Franck Olivier, Cork (IE); Guillaume Lheureux, Cork (IE); Christophe Antoine Hurni, Seattle, WA (US)

(21) Appl. No.: 18/765,036

(22) Filed: Jul. 5, 2024

Related U.S. Application Data
(60) Provisional application No. 63/512,836, filed on Jul. 10, 2023.
(60) Provisional application No. 63/610,274, filed on Dec. 14, 2023.

(51) Int. Cl. H01L 33/00; H01L 33/04; H01L 33/24

(52) U.S. Cl. CPC H01L 33/0095; H01L 33/0075; H01L 33/04; H01L 33/24

(57) ABSTRACT

A method for increasing carrier confinement in light-emitting devices may comprise (1) selectively depositing material over a layered structure of a light-emitting device and (2) defining an emitter size of the light-emitting device by causing the material to disorder regions of a light-emitting layer included in the layered structure. Various other apparatuses, systems, and methods are also disclosed.

### CROSS REFERENCE TO RELATED APPLICATION

This application claims the benefit of U.S. Provisional Application No. 63/512,836 filed Jul. 10, 2023, the disclosure of which is incorporated in its entirety by this reference. This application also claims the benefit of U.S. Provisional Application No. 63/610,274 filed Dec. 14, 2023, the disclosure of which is incorporated in its entirety by this reference.

### BRIEF DESCRIPTION OF DRAWINGS

The accompanying Drawings illustrate a number of exemplary embodiments and are parts of the specification. Together with the following description, the Drawings demonstrate and explain various principles of the instant disclosure.

FIG. 1 is an illustration of an exemplary implementation of a light-emitting device with increased carrier confinement according to one or more embodiments of this disclosure.

FIG. 2 is an illustration of an exemplary light-emitting device with increased carrier confinement according to one or more embodiments of this disclosure.

FIG. 3 is an illustration of an exemplary light-emitting device with increased carrier confinement according to one or more embodiments of this disclosure.

FIG. 4 is an illustration of an exemplary light-emitting device with increased carrier confinement according to one or more embodiments of this disclosure.

FIG. 5 is an illustration of an exemplary implementation of a light-emitting device with increased carrier confinement according to one or more embodiments of this disclosure.

FIG. 6 is an illustration of an exemplary light-emitting device with increased carrier confinement according to one or more embodiments of this disclosure.

FIG. 7 is a flowchart of an exemplary method for increasing carrier confinement in light-emitting devices according to one or more embodiments of this disclosure.

FIG. 8 is an illustration of exemplary AR system that may be used in connection with embodiments of this disclosure.

FIG. 9 is an illustration of an exemplary VR system that may be used in connection with embodiments of this disclosure.

While the exemplary embodiments described herein are susceptible to various modifications and alternative forms, specific embodiments have been shown by way of example in the drawings and will be described in detail herein. However, the exemplary embodiments described herein are not intended to be limited to the particular forms disclosed. Rather, the instant disclosure covers all modifications, combinations, equivalents, and alternatives falling within this disclosure.

### DETAILED DESCRIPTION

The present disclosure is generally directed to apparatuses, systems, and methods for increasing carrier confinement in light-emitting devices. As will be explained in greater detail below, these apparatuses, systems, and methods may provide numerous features and benefits.

In some examples, light-emitting devices with increased carrier confinement may be implemented in connection with artificial reality. Artificial reality may provide a rich, immersive experience in which users are able to interact with virtual objects and/or environments in one way or another. In this context, artificial reality may constitute and/or represent a form of reality that has been altered by virtual objects for presentation to a user. Such artificial reality may include and/or represent virtual reality (VR), augmented reality (AR), mixed reality, hybrid reality, or some combination and/or variation of one or more of the same.

In some examples, micrometer-scale light-emitting diodes (μLEDs) may have the potential to serve as an effective light source in VR/AR technology. In one example, an array of μLEDs may form and/or operate as a self-emitting display of limited dimensions. In this example, the array of μLEDs may offer high resolution and/or a high-contrast ratio in a VR/AR headset.

In some examples, to define the emitting size of a μLED during fabrication, manufacturers may implement a dry-etching process involving reactive ions that bombard the μLED material and/or etch through the active region of the μLED. Unfortunately, this dry-etching process may introduce surface defects and dangling bonds at the etched sidewalls, potentially causing injected electrons to become trapped and thus unable to be converted into photon energy. As a result, this dry-etching process may limit the brightness of the μLED. Such limited brightness may ultimately impair the VR/AR experiences of users wearing VR/AR headsets.

In some examples, manufacturers may implement the methods and/or techniques described herein to define the emitting size of μLEDs without relying exclusively on dry etching. Such methods and/or techniques may involve combinations of partial dry etching, band-gap tuning, and/or atomic diffusion in regions outside of the active emitting region. In one example, band-gap tuning may include and/or represent layer disordering, such as quantum-well intermixing (QWI). In certain implementations, layer disordering may be performed and/or accomplished in several ways. For example, impurity-free disordering and/or impurity-induced disordering may be performed and/or accomplished via ion implantation, atomic diffusion, and/or impurity diffusion.

In some examples, impurity-free layer disordering may include and/or represent a vacancy-induced defect-free solution that alters the band gap of a semiconductor outside of the light-emitting and/or active region of a μLED. For example, impurity-free layer disordering may be induced within the light-emitting and/or active region via Group III element extraction. In this example, the Group III element extraction may involve and/or be implemented at an elevated temperature that exceeds a certain threshold (e.g., temperatures of approximately 500° C. or more).

In one example, impurity-free layer disordering may include and/or represent a dielectric material, such as silicon dioxide (SiO₂), and/or another suitable material. In this example, at elevated temperatures (e.g., temperatures of approximately 500° C. or more), the dielectric and/or other suitable material may extract Group III elements from a layer that includes Group III-V elements in a μLED. The presence of a dielectric material at these elevated temperatures may also provide thermal stress to the wafer surface. This thermal stress may generate point defects that diffuse into the semiconductor and allow interdiffusion to occur between the Group III elements in the light-emitting region, thereby resulting in layer disordering and bandgap tuning. This extraction may lead to, result in, and/or cause elemental and/or vacancy diffusion. Once the vacancies reach the light-emitting and/or active region of the μLED, the Group III elements between the light-emitting and/or active regions (e.g., quantum wells) and barriers may intermix to create a wider band gap than the light-emitting and/or active region. In certain implementations, the elevated temperature used to extract the Group III element may be sufficient to thermally anneal the dielectric layer.

For impurity-induced disordering, atomic diffusion and/or ion implantation may introduce an external species into the μLED. In one example, at elevated temperatures, this newly introduced external species may diffuse into quantum-confined structures, such as quantum dots and/or quantum wells of one or more semiconductors included in the μLED. Such diffusion may cause intermixing in those semiconductors. This intermixing may lead to and/or result in a wider band gap than the light-emitting and/or active region.

In some examples, combinations of impurity-free disordering and/or impurity-induced disordering may serve to form and/or create planar or partially etched μLEDs with sharpened wide band-gap profiles at the edges of their respective light-emitting regions. Such combinational disordering techniques may cause electrons to be repelled at the intermixed-region interfaces, thereby facilitating and/or promoting high lateral electron concentration in the light-emitting and/or active regions. Accordingly, the photon emission of μLEDs created from such combinational disordering techniques may be more localized. As a result, such μLEDs may provide and/or supply increased brightness capable of improving and/or advancing VR/AR display technologies.

In some examples, a system or method for increasing carrier confinement in light-emitting devices may implement vertical layer disordering in a specified patterned region. In one example, the system or method may include and/or involve using a material or source that induces impurity-induced disordering (e.g., atomic diffusion, ion implantation, or other method of impurity diffusion) or impurity-free disordering layer disordering in the light-emitting layer of the light-emitting devices. In certain implementations, the light-emitting devices may include and/or represent mesa etchings at different depths and/or one or more mesa etches with layer disordering.

In some examples, a system or method for increasing carrier confinement in light-emitting devices may include and/or involve partially removing material from a μLED with lateral carrier confinement. The partial material removal can be accomplished via several techniques (including dry etching, wet etching, etc.) on one side of the light-emitting layer. In one example, the system or method may include and/or involve replacing the partially removed material with selective area growth (SAG) in patterned regions. In this example, the SAG may introduce pathways to grow tunnel junctions in specified regions.

In some examples, the benefits of the SAG for small-area emitters may mitigate and/or eliminate the need to remove material, which has the potential to disrupt the crystalline quality and/or introduce surface recombination and defects at the edges. The partial SAG process may be performed on only one side of the light-emitting layer. Subsequent growth may facilitate and/or allow for small-area growth of tunnel junctions to convert to opposite conductivities and/or polarities in specified areas. In one example, regrowth above the oxide layer may occur under certain conditions. In this example, such regrowth may lead to and/or result in a triangular configuration and/or arrangement for increased light extraction.

In some examples, a system or method for increasing carrier confinement in light-emitting devices may include and/or involve a mesa etched in the light-emitting region of a μLED. In one example, the system or method may include and/or involve partially removing material (e.g., to get closer to the light-emitting region) and then etching a mesa through the light-emitting region. As a result, the system or method may increase and/or improve light extraction by adding a mirror at one or more sides and/or walls of the μLED.

In some examples, a system or method for increasing carrier confinement in light-emitting devices may create layer disordering along the borders of the light-emitting region. In one example, the percentage of area whose material is layer-disordered may vary. The diffusion and/or layer disordering may be performed and/or accomplished to define a sharp interface between the light-emitting region and the disordered material for a wide band-gap offset. The system or method may be applied to Group III-V inorganic semiconductor LEDs engineered to emit across the ultraviolet and/or visible spectrum (e.g., broad portion of the visible spectrum that includes red, green, and blue). The system or method may be detected using focused ion beam (FIB) technology and/or secondary ion mass spectroscopy (SIMS).

In some examples, the system or method may implement a combination of high temperature diffusion using SiO₂ or specific external sources for atomic diffusion to create changes in the semiconductor band gap. In one example, the system or method may be designed configured, and/or implemented as arrays of single pixels for display applications. In certain implementations, the size of the μLEDs may be approximately 50 microns or less.

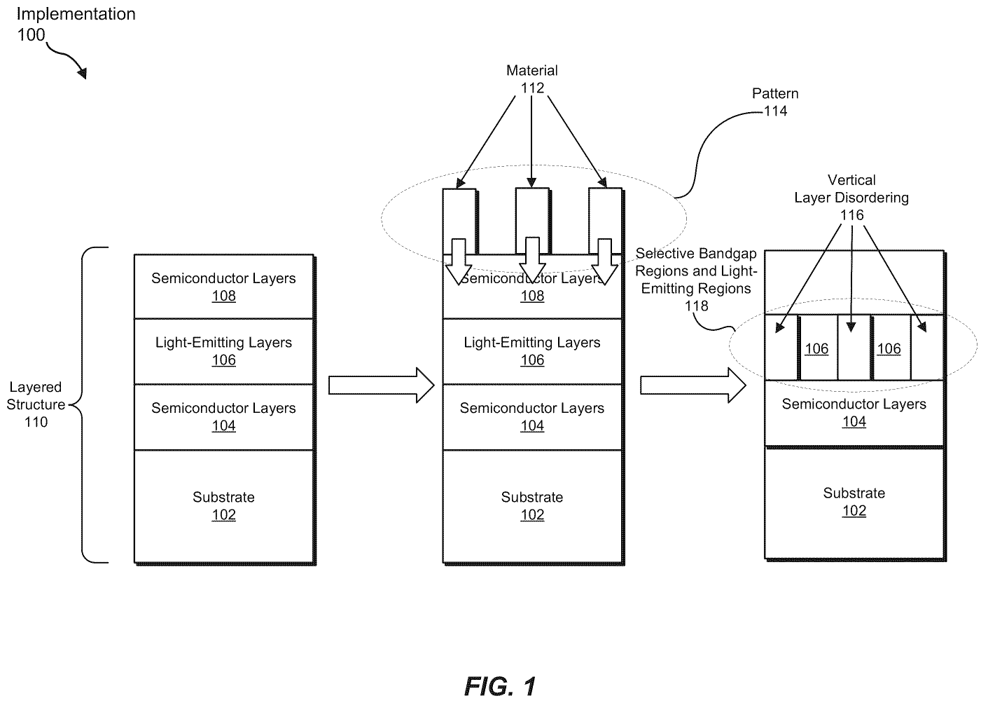

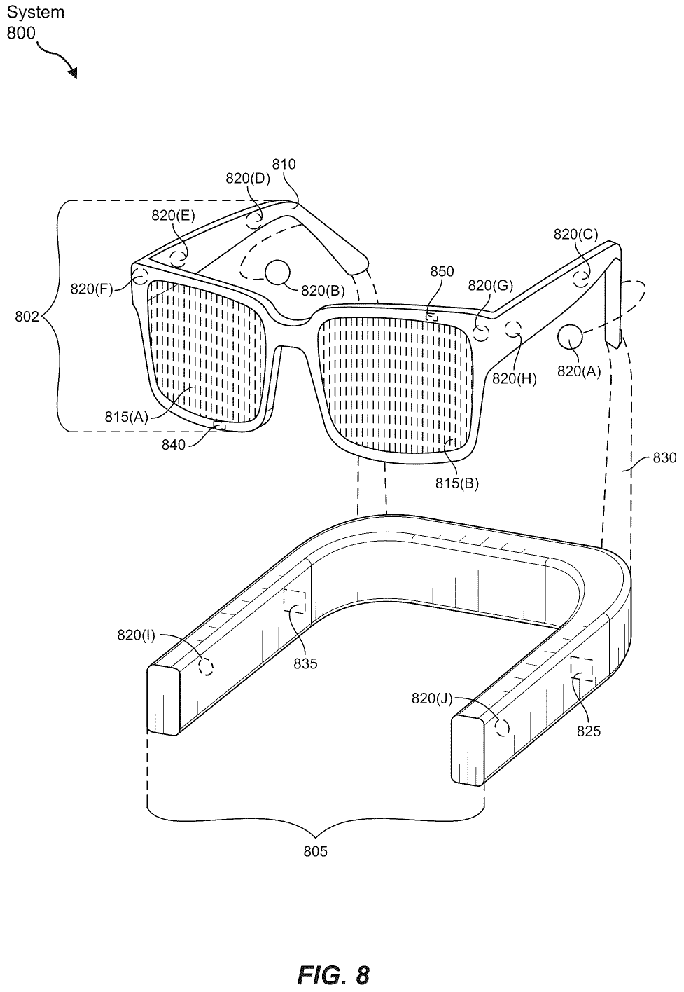

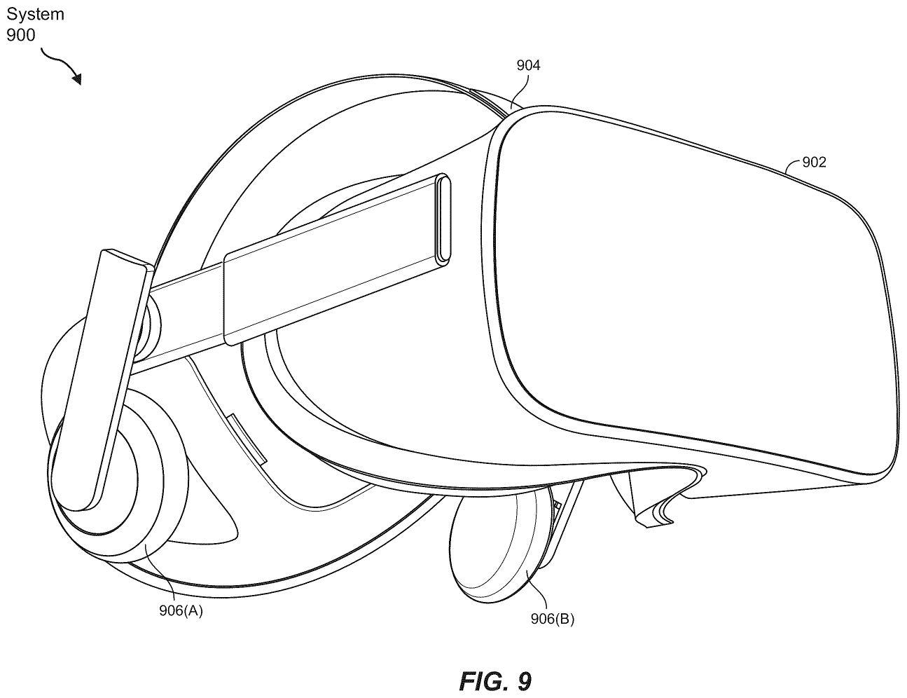

The following will provide, with reference to FIGS. 1-7, detailed descriptions of exemplary apparatuses, devices, systems, components, configurations, methods, and/or implementations for increasing carrier confinement in light-emitting devices. The discussion corresponding to FIGS. 8-9 will provide detailed descriptions of types of exemplary artificial-reality devices, wearables, and/or associated systems capable of increasing carrier confinement in light-emitting devices.

FIG. 1 illustrates an exemplary implementation 100 of a light-emitting device with increase carrier confinement. As illustrated in FIG. 1, exemplary implementation 100 of the light-emitting device may include and/or represent a layered structure 110. In some examples, layered structure 110 may include and/or represent a substrate 102, semiconductor layers 104, light-emitting layers 106, and/or semiconductor layers 108. In one example, implementation 100 may include and/or involve selectively depositing material 112 over layered structure 110 of the light-emitting device in a pattern 114. In this example, implementation 100 may also include and/or involve defining an emitter size of the light-emitting device by causing material 112 to disorder regions of light-emitting layers 106 included in layered structure 110.

In some examples, light-emitting layers 106 may be disposed, positioned, and/or located between semiconductor layers 104 and 108. Additionally or alternatively, substrate 102 may be coupled and/or secured to semiconductor layers 104 opposite light-emitting layers 106.

In some examples, implementation 100 may include and/or involve inducing impurity-free disordering of material 112 within light-emitting layers 106 in any of a variety of different ways. For example, implementation 100 may involve and/or utilize ion implantation, atomic diffusion, and/or impurity diffusion to achieve impurity-free disordering of material 112. Additionally or alternatively, implementation 100 may include and/or involve causing impurity-induced disordering of material 112 within light-emitting layers 106 in any of a variety of different ways. For example, implementation 100 may involve and/or utilize ion implantation, atomic diffusion, and/or impurity diffusion to achieve disordering of material 112.

In some examples, implementation 100 may include and/or involve applying at least one fabrication process to layered structure 110 to define the emitter size of the light-emitting device. In one example, implementation 100 may include and/or involve applying such a fabrication process outside light-emitting layers 106 (e.g., in one or more of semiconductor layers 104 and 108). Additionally or alternatively, implementation 100 may include and/or involve applying such a fabrication process to light-emitting layers 106.

In some examples, implementation 100 may display, show, and/or illustrate a portion of a fabrication process (e.g., from left to right in FIG. 1) in which the light-emitting device is created, formed, and/or improved. In one example, the fabrication process may include and/or involve inducing elemental and/or vacancy diffusion in layered structure 110 to widen the band gap of light-emitting layers 106 by increasing the temperature of material 112 (e.g., to 500° C. or greater) and/or extracting an element (e.g., a Group III element, scandium, yttrium, lutetium, lawrencium, etc.) from one of the layers included in layered structure 110 as a result of the increased temperature. Examples of such a fabrication process includes, without limitation, partial dry etching, band-gap tuning, impurity diffusion, combinations or variations of one or more of the same, and/or any other suitable fabrication process. In certain implementations, the diffusion of vacancies may induce redistribution of elements between adjacent layers, thereby leading to the formation of a mixed layer. In such implementations, the mixed layer may include and/or represent elements extracted and/or redistributed from the adjacent layers.

In some examples, implementation 100 may include and/or involve implanting and/or depositing material 112 atop and/or into semiconductor layers 108 at 0 degrees or at an angle. In one example, implementation 100 may include and/or involve thermally diffusing material 112 into light-emitting layers 106 via elemental and/or vacancy diffusion. By doing so, implementation 100 may introduce and/or cause layer disordering in light-emitting layers 106. In one example, the thermal diffusion of material 112 may result in and/or lead to vertical layer disordering 116 in light-emitting layers 106. Accordingly, implementation 100 may include and/or involve inducing vertical layer disordering 116 of material 112 within light-emitting layers 106 to achieve lateral carrier confinement in at least one layer included layered structure 110. In certain implementations, vertical layer disordering 116 may cause, lead to, and/or result in selective bandgap regions and light-emitting regions 118 in light-emitting layer 106.

In some examples, the term “layer disordering” may include, represent, and/or constitute the process of changing and/or modifying a composition of a material, layer, and/or region of layered structure 110. In one example, disorder within a layer (e.g., light-emitting layers 106 and/or an adjacent semiconductor layer) may include and/or represent one or more changes. Such changes may occur relative to one or more surrounding layers (e.g., semiconductor layers 104 and 108) that are unimpacted and/or unaffected by the layer disordering. Additionally or alternatively, such changes may occur relative to the previous state, condition, and/or configuration of the layer being affected and/or impacted. In certain implementations, one goal and/or purpose of layer disordering may be to change the band gap of one or more of the layers included in layered structure 110. As a result of such layer disordering, the carriers in the unchanged layers or regions of layered structure 110 may be confined and/or restricted (e.g., toward the center). Accordingly, the layer disordering may cause and/or achieve lateral carrier confinement.

In some examples, material 112 may diffuse into light-emitting layers 106 as a result of impurity-induced disordering of light-emitting layers 106. In other examples, material 112 may not diffuse into light-emitting layers 106 as a result of impurity-free disordering of light-emitting layers 106.

In some examples, the light-emitting device may include and/or represent an emitter that emits light. In one example, the emitter may correspond to and/or represent the light-emitting area and/or region of layered structure 110 and/or the light-emitting device. For example, the emitter may include and/or represent all or a portion of light-emitting layers 106. Accordingly, the emitter size defined by implementation 100 may include and/or represent the size of the area and/or region of layered structure 110 that emits light, as opposed to the overall size of layered structure 110 or the light-emitting device. In some examples, the overall physical size and/or dimensions of layered structure 110 and/or the light-emitting device may remain the same, unchanged, and/or constant before and after the layer-disordering process.

In some examples, after completion of the layer-disordering process, carriers (e.g., electrons and electron holes) may be confined to a small region and/or area of layered structure 110. For example, carriers may be unable to spread laterally as a result of the confinement achieved in layered structure 110 via layer disordering. In this example, such carrier confinement may facilitate, support, and/or promote smaller form factors. Additionally or alternatively, such carrier confinement may increase and/or improve the brightness of light emitted by the light-emitting device.

In some examples, such carrier confinement may increase and/or improve brightness of the light-emitting device by keeping carriers away from the side walls of layered structure 110 to avoid recombination, which causes loss (e.g., photon loss and/or loss of brightness). Additionally or alternatively, such carrier confinement may serve to couple more photons with a waveguide of a VR/AR headset to collimate the corresponding light. Without sufficient coupling, the photons may be lost from the optical path of the VR/AR headset, thereby potentially resulting in decreased brightness. In one example, the collimation of light may be more efficient when the emitter size of the light-emitting device is smaller, thereby potentially increasing the brightness.

In some examples, implementation 100 may include and/or involve tuning a band gap of one or more of the layers included in layered structure 110 via quantum-well intermixing (QWI). In one example, implementation 100 may include and/or involve defining the emitter size by disposing a barrier and/or wall between quantum-well regions of layered structure 110 (e.g., within light-emitting layers 106) and/or causing at least one of semiconductor layers 104 and 108 to avoid overlapping the barrier and/or wall. In certain implementations, the light-emitting device may be sized and/or dimensioned at 50 microns or less. For example, light-emitting layers 106 and semiconductor layers 104 and 108 may be collectively sized at 50 microns or less.

In some examples, implementation 100 may include and/or represent sharpening a band-gap profile of an edge and/or interface between material 112 and/or one or more of semiconductor layers 104, light-emitting layers 106, and/or semiconductor layers 108. In such examples, by sharpening the band-gap profile in this way, implementation 100 may cause the band-gap profile to be more step-like and/or to include or exhibit step-like behavior and/or characteristics. In one example, implementation 100 may include and/or involve completing the band-gap tuning at certain edges and/or interfaces between material 112 and light-emitting layers 106 to avoid gradients and/or overlaps in the layer disordering.

In some examples, implementation 100 may include and/or involve removing semiconductor material from an edge and/or interface of at least one layer included in layered structure 110. Additionally or alternatively, implementation 100 may include an/or involve causing selective area growth (SAG) at the edge and/or interface of at least one layer included in layered structure 110. Either way, implementation 100 may further include and/or involve causing material 112 to disorder the edge and/or interface without overlapping the layer's semiconductor material to reduce non-radiative losses.

In some examples, material 112 may be any type or form of substance, element, and/or compound that promotes and/or induces layer disordering. Additionally or alternatively, material 112 may include and/or represent any type or form of substance used for intermixing, such as impurity diffusion (e.g., ion implantation and/or atomic diffusion) and/or impurity-free diffusion (e.g., Group III element extraction at elevated temperatures using dielectrics or high-stress dielectric films to generate point defects at the surface). In one example, material 112 may include and/or represent a dielectric, an ion-implantation material, and/or an atomic-diffusion material. Additional examples of material 112 include, without limitation, p-type dopants, n-type dopants, zinc, carbon, magnesium, neutral ions, nitrogen, oxygen, combinations or variations of one or more of the same, and/or any other suitable material.

In some examples, light-emitting layers 106 and/or semiconductor layers 104 and 108 may include and/or represent various semiconductor materials. Examples of such semiconductor materials include, without limitation, Group III materials, Group IV materials, Group V materials, silicon, silicon carbide, boron nitride, boron phosphide, boron arsenide, aluminum nitride, aluminum phosphide, germanium, gallium arsenide, gallium phosphide, combinations or variations of one or more of the same, and/or any other suitable materials.

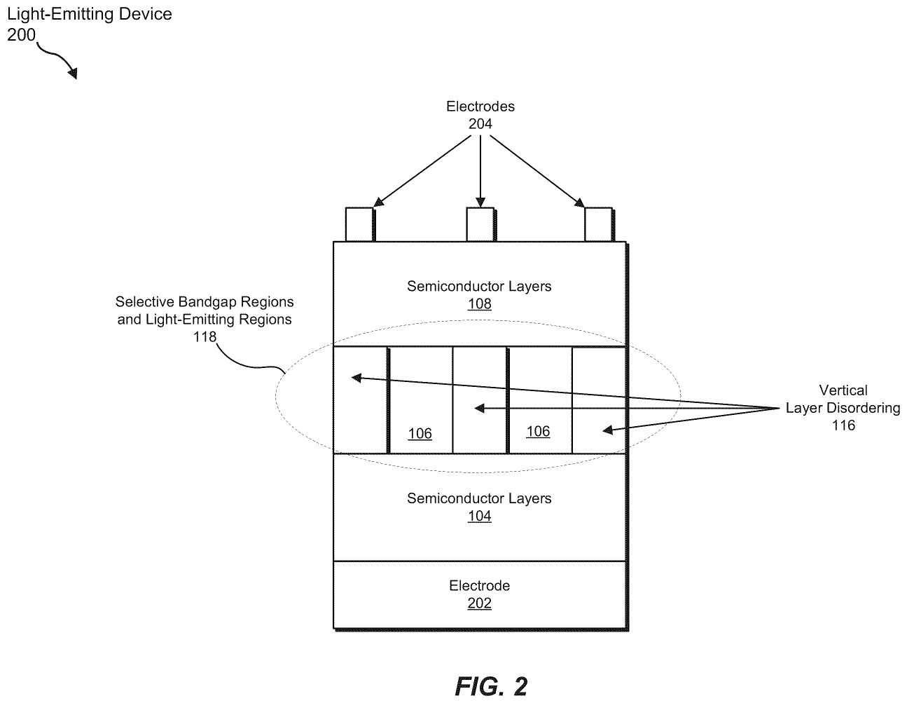

FIG. 2 illustrates an exemplary light-emitting device 200 with increased carrier confinement. In some examples, light-emitting device 200 may include and/or represent certain components, configurations, and/or features that perform and/or provide functionalities that are similar and/or identical to those described above in connection with FIG. 1. As illustrated in FIG. 2, light-emitting device 200 may include and/or represent light-emitting layers 106 positioned between semiconductor layers 104 and 108. In one example, light-emitting layers 106 may include and/or represent selective bandgap regions and light-emitting regions 118 configured and/or arranged with and/or as a result of vertical layer disordering 116. In certain implementations, the light-emitting regions may constitute and/or represent pixels within light-emitting layer 106.

In some examples, light-emitting device 200 may include and/or represent an electrode 202 coupled and/or secured to semiconductor layers 104 opposite light-emitting layers 106. In one example, light-emitting device 200 may also include and/or represent one or more electrodes 204 coupled and/or secured to semiconductor layers 108 opposite light-emitting layers 106. In certain implementations, one or more of electrodes 202 and 204 may be used to activate and/or drive light emission via light-emitting layers 106.

In some examples, light-emitting device 200 may each include and/or represent any type or form of device capable of producing, emitting, and/or transferring light energy. In one example, light-emitting device 200 may include and/or represent a μLED. Additional examples of light-emitting device 200 include, without limitation, light-emitting diodes (LEDs), laser diodes, vertical cavity surface emitting lasers (VCSELs), vertical external cavity surface emitting laser (VECSELs), resonant cavity LEDs (RCLEDs), organic LEDS (OLEDs), edge emitters, top or bottom emitters, lasers, surface-emitting lasers, superluminescent LEDs (SLEDs), combinations or variations of one or more of the same, and/or any other suitable light-emitting devices.

In some examples, an array of light-emitting devices 200 may be grouped, included, and/or incorporated in a single unit, element, component, and/or die. Additionally or alternatively, an array of light-emitting devices 200 may include and/or represent a set or group of discrete units, elements, components, and/or dies. In certain implementations, an array of light-emitting devices 200 may be included and/or incorporated in a VR/AR headset.

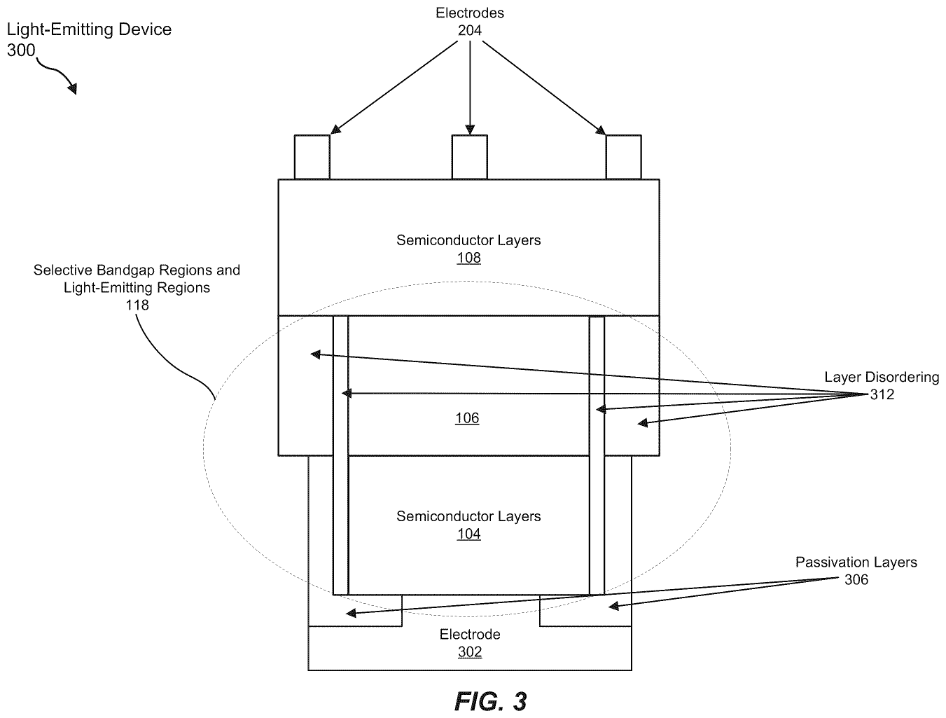

FIG. 3 illustrates an exemplary light-emitting device 300 with increased carrier confinement. In some examples, light-emitting device 300 may include and/or represent certain components, configurations, and/or features that perform and/or provide functionalities that are similar and/or identical to those described above in connection with either FIG. 1 or FIG. 2. As illustrated in FIG. 3, light-emitting device 300 may include and/or represent light-emitting layers 106 positioned between semiconductor layers 108 and 104. In one example, light-emitting layers 106 and/or semiconductor layers 104 may include and/or represent selective bandgap regions and light-emitting regions 118 configured and/or arranged with and/or as a result of layer disordering 312. In this example, semiconductor layers 104 may include and/or represent layer disordering along their side walls and/or barriers.

In some examples, light-emitting device 300 may include and/or represent an electrode 302 coupled and/or secured to semiconductor layers 104 opposite light-emitting layers 106 and/or passivation layers 306. In one example, passivation layers 306 may be coupled to and/or interfaced with electrode 302, semiconductor layers 104, and/or regions affected by layer disordering 312. Light-emitting device 300 may also include and/or represent electrodes 204 coupled and/or secured to semiconductor layers 108 opposite light-emitting layers 106. In certain implementations, one or more of electrodes 202 and 204 may be used to activate and/or drive light emission via light-emitting layers 106.

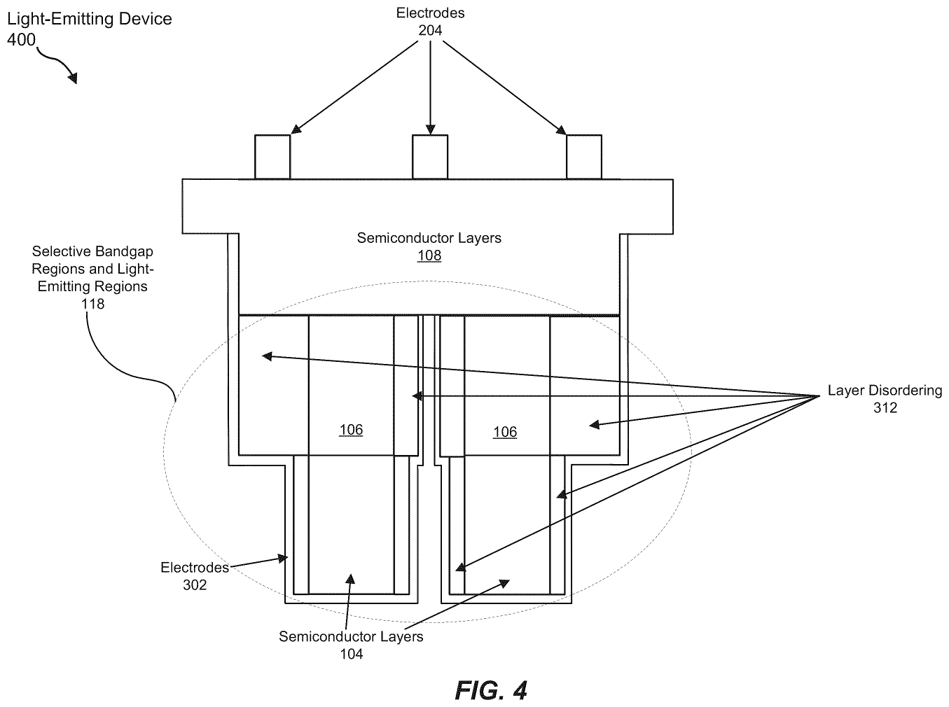

FIG. 4 illustrates an exemplary light-emitting device 400 with increased carrier confinement. In some examples, light-emitting device 400 may include and/or represent certain components, configurations, and/or features that perform and/or provide functionalities that are similar and/or identical to those described above in connection with any of FIGS. 1-3. As illustrated in FIG. 4, light-emitting device 400 may include and/or represent light-emitting layers 106 positioned between semiconductor layers 108 and 104. In one example, light-emitting layers 106 and/or semiconductor layers 104 may include and/or represent selective bandgap regions and light-emitting regions 118 configured and/or arranged with and/or as a result of layer disordering 312. In this example, light-emitting layers 106 and/or semiconductor layers 104 may include and/or represent layer disordering along one or more of the corresponding side walls and/or barriers.

In some examples, light-emitting device 400 may include and/or represent electrode 302 coupled and/or secured to semiconductor layers 104 opposite light-emitting layers 106. In one example, light-emitting device 300 may also include and/or represent electrodes 204 coupled and/or secured to semiconductor layers 108 opposite light-emitting layers 106. In certain implementations, one or more of electrodes 302 and 204 may be used to activate and/or drive light emission via light-emitting layers 106.

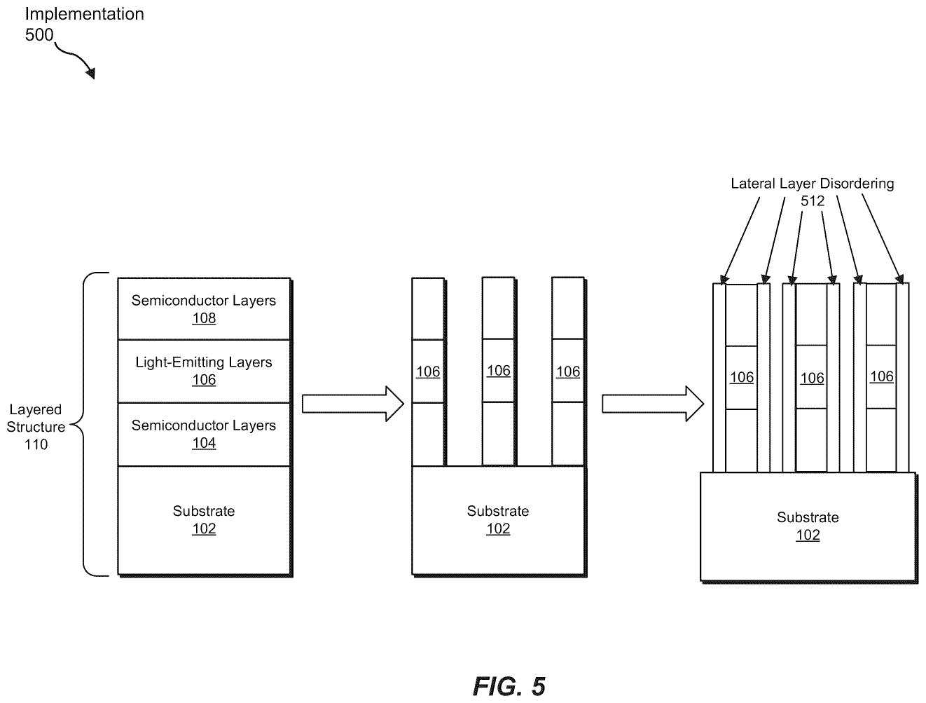

FIG. 5 illustrates an exemplary implementation 500 of a light-emitting device with increased carrier confinement. In some examples, implementation 500 may include and/or represent certain components, configurations, and/or features that perform and/or provide functionalities that are similar and/or identical to those described above in connection with any of FIGS. 1-4. As illustrated in FIG. 5, exemplary implementation 500 of the light-emitting device may include and/or represent layered structure 110.

In some examples, layered structure 110 may include and/or represent substrate 102, semiconductor layers 104, light-emitting layers 106, and/or semiconductor layers 108. In one example, implementation 500 may include and/or involve selectively depositing material 112 over and/or around layered structure 110 of the light-emitting device in a certain pattern. In this example, implementation 500 may also include and/or involve defining the emitter size of the light-emitting device by causing material 112 to disorder regions of light-emitting layers 106 included in layered structure 110. To do so, implementation 500 may include and/or involve lateral layer disordering 512 of light-emitting layer 106 via material 112.

In some examples, light-emitting layers 106 may be disposed, positioned, and/or located between semiconductor layers 104 and 108. Additionally or alternatively, substrate 102 may be coupled and/or secured to semiconductor layers 104 opposite light-emitting layers 106. Implementation 500 may include and/or represent a process involved in the manufacture of 3 dry etched μLEDs.

In some examples, implementation 500 may display, show, and/or illustrate a portion of a fabrication process (e.g., from left to right in FIG. 5) in which the light-emitting device is created, formed, and/or improved. In one example, the fabrication process may include and/or involve inducing elemental and/or vacancy diffusion in layered structure 110 to widen the band gap of light-emitting layers 106 by increasing the temperature of material 112 (e.g., to 500° C. or greater) and/or extracting an element (e.g., a Group III element, scandium, yttrium, lutetium, lawrencium, etc.) from one of the layers included in layered structure 110 as a result of the increased temperature. Examples of such a fabrication process includes, without limitation, etching, partial dry etching, band-gap tuning, impurity diffusion, combinations or variations of one or more of the same, and/or any other suitable fabrication process.

In some examples, implementation 500 may include and/or involve implanting and/or depositing material 112 atop and/or into semiconductor layers 108 at 0 degrees or at an angle. In one example, implementation 500 may include and/or involve thermally diffusing material 112 into semiconductor layers 104, light-emitting layers 106, and/or semiconductor layers 108 via elemental and/or vacancy diffusion. By doing so, implementation 500 may introduce and/or cause layer disordering in semiconductor layers 104, light-emitting layers 106, and/or semiconductor layers 108. In one example, the thermal diffusion of material 112 may result in and/or lead to lateral layer disordering 512 in light-emitting layers 106. In certain examples, the thermal diffusion of material 112 may lead to and/or result in selective bandgap regions and/or light-emitting regions being configured and/or arranged through lateral layer disordering 512. Additionally or alternatively, implementation 500 may include and/or involve inducing lateral layer disordering 512 of material 112 within light-emitting layers 106 to achieve lateral carrier confinement in at least one layer included layered structure 110.

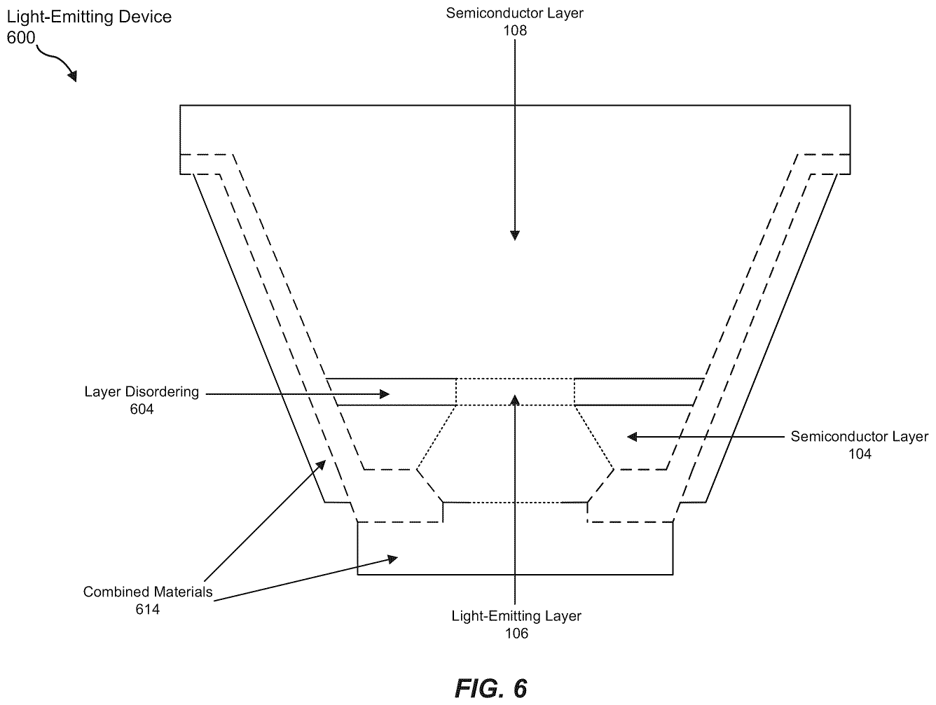

FIG. 6 illustrates an exemplary light-emitting device 600 with increased carrier confinement. In some examples, light-emitting device 600 may include and/or represent certain components, configurations, and/or features that perform and/or provide functionalities that are similar and/or identical to those described above in connection with any of FIGS. 1-5. As illustrated in FIG. 6, light-emitting device 600 may include and/or represent light-emitting layers 106 positioned between semiconductor layers 104 and 108. In one example, light-emitting layers 106 may implement and/or exhibit layer disordering 604.

In some examples, light-emitting device 600 may include and/or represent combined materials 614 coupled and/or secured to semiconductor layers 104 and/or one or more of the corresponding side walls and/or barriers. In one example, combined materials 614 may include and/or represent dielectrics and/or metals that collectively facilitate, support, and/or promote increased light extraction efficiency.

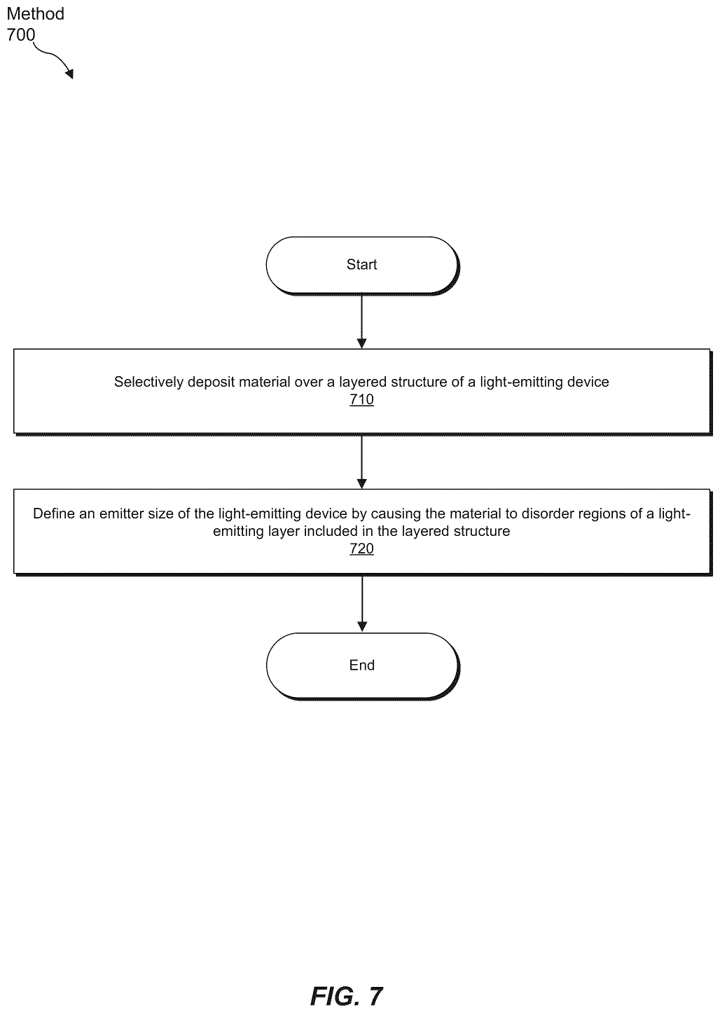

FIG. 7 is a flow diagram of an exemplary method 700 for increasing carrier confinement in light-emitting devices. In one example, the steps shown in FIG. 7 may be performed during the manufacture and/or assembly of a light-emitting device and/or an artificial-reality device. Additionally or alternatively, the steps shown in FIG. 7 may incorporate and/or involve various sub-steps and/or variations consistent with one or more of the descriptions provided above in connection with FIGS. 1-6.

As illustrated in FIG. 7, method 700 may include and/or involve the step of selectively deposit material over a layered structure of a light-emitting device (710). Step 710 may be performed in a variety of ways, including any of those described above in connection with FIGS. 1-6. For example, an AR equipment manufacturer or subcontractor may selectively deposit material over a layered structure of a light-emitting device.

In some examples, method 700 may also include the step of defining an emitter size of the light-emitting device by causing the material to disorder regions of a light-emitting layer included in the layered structure (720). Step 720 may be performed in a variety of ways, including any of those described above in connection with FIGS. 1-6. For example, the AR equipment manufacturer or subcontractor may define an emitter size of the light-emitting device by causing the material to disorder regions of a light-emitting layer included in the layered structure.

### [INVENTOR(S): THE FOLLOWING SECTION IS RESTATEMENT OF THE CLAIMS FOR LEGAL PURPOSES. FEEL FREE TO SKIP OVER THIS SECTION AND FOCUS YOUR REVIEW ON THE CLAIMS]

### Example Embodiments

Example 1: A method comprising (1) selectively depositing material over a layered structure of a light-emitting device and (2) defining an emitter size of the light-emitting device by causing the material to disorder regions of a light-emitting layer included in the layered structure.

Example 2: The method of Example 1, wherein causing the material to disorder the regions of the light-emitting layer comprises inducing impurity-free disordering of the material within the light-emitting layer via Group III element extraction at a temperature that exceeds a certain threshold.

Example 3: The method of either Example 1 or Example 2, wherein causing the material to disorder the regions of the light-emitting layer comprises causing impurity-induced disordering of the material within the light-emitting layer via at least one of ion implantation and/or atomic diffusion.

Example 4: The method of any of Examples 1-3, wherein defining the emitter size of the light-emitting device comprises defining the emitter size of the light-emitting device by applying at least one fabrication process to the layered structure outside the light-emitting layer.

Example 5: The system of any of Examples 1-4, wherein the fabrication process comprises at least one of partial dry etching, band-gap tuning, and/or impurity diffusion.

Example 6: The method of any of Examples 1-5, wherein the fabrication process comprises inducing elemental diffusion in the layered structure to widen a band gap of the light-emitting layer by increasing a temperature of the material and extracting an element from at least one layer included in the layered structure as a result of the increased temperature.

Example 7: The method of any of Examples 1-6, wherein defining the emitter size of the light-emitting device comprises tuning a band gap of at least one of the layers included in the layered structure via quantum-well intermixing (QWI).

Example 8: The method of any of Examples 1-7, wherein defining the emitter size of the light-emitting device comprises (1) disposing a barrier between quantum-well regions of the layered structure and (2) causing at least one of the semiconductor layers to avoid overlapping the barrier.

Example 9: The method of any of Examples 1-8, wherein the light-emitting layer and the semiconductor layers are collectively sized at 50 microns or less.

Example 10: The method of any of Examples 1-9, wherein causing the material to disorder the regions of the light-emitting layer comprises at least one of (1) inducing vertical disordering of the material within the light-emitting layer to achieve lateral carrier confinement in at least one layer included the layered structure or (2) inducing lateral disordering of the material within the light-emitting layer to achieve lateral carrier confinement in at least one layer included the layered structure.

Example 11: The method of any of Examples 1-10, wherein the material comprises a dielectric.

Example 12: The method of any of Examples 1-11, wherein causing the material to disorder the regions of the light-emitting layer comprises sharpening a band-gap profile of an edge of at least one layer included in the layered structure.

Example 13: The method of any of Examples 1-12, further comprising (1) removing semiconductor material from an edge of at least one layer included in the layered structure and (2) causing the material to disorder the edge to reduce non-radiative losses.

Example 14: The method of any of Examples 1-13, further comprising (1) causing selective area growth at an edge of at least one layer included in the layered structure and (2) causing the material to disorder the edge to reduce non-radiative losses.

Example 15: The method of any of Examples 1-14, further comprising implementing the light-emitting device in an artificial-reality device dimensioned to be worn by a user.

Example 16: A light-emitting device comprising (1) a layered structure comprising a light-emitting layer disposed between semiconductor layers, (2) material selectively applied to the layered structure, and (3) an emitter whose size is defined by regions of the light-emitting layer that are disordered by the material.

Example 178: The light-emitting device of Example 16, wherein the regions of the light-emitting layer are either vertically disordered or laterally disordered by the material.

Example 18: The light-emitting device of Example 16 or Example 17, wherein the light-emitting layer is disposed between semiconductor layers included in the layered structure.

Example 19: The light-emitting device of any of Examples 16-18, wherein the light-emitting layer is disposed between semiconductor layers included in the layered structure.

Example 20: A system comprising (1) an artificial-reality device dimensioned to be worn by a user and (2) a light-emitting device incorporated in the artificial-reality device, the light-emitting device comprising (A) a layered structure comprising a light-emitting layer disposed between semiconductor layers, (B) material selectively applied to the layered structure, and (C) an emitter whose size is defined by regions of the light-emitting layer that are disordered by the material.

### [INVENTORS: THE FOLLOWING SECTION IS BOILERPLATE]

Embodiments of the present disclosure may include or be implemented in conjunction with various types of artificial-reality systems. Artificial reality is a form of reality that has been adjusted in some manner before presentation to a user, which may include, for example, a VR, an AR, a mixed reality, a hybrid reality, or some combination and/or derivative thereof. Artificial-reality content may include completely computer-generated content or computer-generated content combined with captured (e.g., real-world) content. The artificial-reality content may include video, audio, haptic feedback, or some combination thereof, any of which may be presented in a single channel or in multiple channels (such as stereo video that produces a three-dimensional (3D) effect to the viewer). Additionally, in some embodiments, artificial reality may also be associated with applications, products, accessories, services, or some combination thereof, that are used to, for example, create content in an artificial reality and/or are otherwise used in (e.g., to perform activities in) an artificial reality.

Artificial-reality systems may be implemented in a variety of different form factors and configurations. Some artificial-reality systems may be designed to work without near-eye displays (NEDs). Other artificial-reality systems may include an NED that also provides visibility into the real world (such as, e.g., AR system 800 in FIG. 8) or that visually immerses a user in an artificial reality (such as, e.g., VR system 900 in FIG. 9). While some artificial-reality devices may be self-contained systems, other artificial-reality devices may communicate and/or coordinate with external devices to provide an artificial-reality experience to a user. Examples of such external devices include handheld controllers, mobile devices, desktop computers, devices worn by a user, devices worn by one or more other users, and/or any other suitable external system.

Turning to FIG. 8, AR system 800 may include an eyewear device 802 with a frame 810 configured to hold a left display device 815(A) and a right display device 815(B) in front of a user's eyes. Display devices 815(A) and 815(B) may act together or independently to present an image or series of images to a user. While AR system 800 includes two displays, embodiments of this disclosure may be implemented in AR systems with a single NED or more than two NEDs.

In some embodiments, AR system 800 may include one or more sensors, such as sensor 840. Sensor 840 may generate measurement signals in response to motion of AR system 800 and may be located on substantially any portion of frame 810. Sensor 840 may represent one or more of a variety of different sensing mechanisms, such as a position sensor, an inertial measurement unit (IMU), a depth camera assembly, a structured light emitter and/or detector, or any combination thereof. In some embodiments, AR system 800 may or may not include sensor 840 or may include more than one sensor. In embodiments in which sensor 840 includes an IMU, the IMU may generate calibration data based on measurement signals from sensor 840. Examples of sensor 840 may include, without limitation, accelerometers, gyroscopes, magnetometers, other suitable types of sensors that detect motion, sensors used for error correction of the IMU, or some combination thereof.

In some examples, AR system 800 may also include a microphone array with a plurality of acoustic transducers 820(A)-820(J), referred to collectively as acoustic transducers 820. Acoustic transducers 820 may represent transducers that detect air pressure variations induced by sound waves. Each acoustic transducer 820 may be configured to detect sound and convert the detected sound into an electronic format (e.g., an analog or digital format). The microphone array in FIG. 8 may include, for example, ten acoustic transducers: 820(A) and 820(B), which may be designed to be placed inside a corresponding ear of the user, acoustic transducers 820(C), 820(D), 820(E), 820(F), 820(G), and 820(H), which may be positioned at various locations on frame 810, and/or acoustic transducers 820(I) and 820(J), which may be positioned on a corresponding neckband 805.

In some embodiments, one or more of acoustic transducers 820(A)-(J) may be used as output transducers (e.g., speakers). For example, acoustic transducers 820(A) and/or 820(B) may be earbuds or any other suitable type of headphone or speaker.

The configuration of acoustic transducers 820 of the microphone array may vary. While AR system 800 is shown in FIG. 8 as having ten acoustic transducers 820, the number of acoustic transducers 820 may be greater or less than ten. In some embodiments, using higher numbers of acoustic transducers 820 may increase the amount of audio information collected and/or the sensitivity and accuracy of the audio information. In contrast, using a lower number of acoustic transducers 820 may decrease the computing power required by an associated controller 850 to process the collected audio information. In addition, the position of each acoustic transducer 820 of the microphone array may vary. For example, the position of an acoustic transducer 820 may include a defined position on the user, a defined coordinate on frame 810, an orientation associated with each acoustic transducer 820, or some combination thereof.

Acoustic transducers 820(A) and 820(B) may be positioned on different parts of the user's ear, such as behind the pinna, behind the tragus, and/or within the auricle or fossa. Or, there may be additional acoustic transducers 820 on or surrounding the ear in addition to acoustic transducers 820 inside the ear canal. Having an acoustic transducer 820 positioned next to an ear canal of a user may enable the microphone array to collect information on how sounds arrive at the ear canal. By positioning at least two of acoustic transducers 820 on either side of a user's head (e.g., as binaural microphones), AR system 800 may simulate binaural hearing and capture a 3D stereo sound field around about a user's head. In some embodiments, acoustic transducers 820(A) and 820(B) may be connected to AR system 800 via a wired connection 830, and in other embodiments acoustic transducers 820(A) and 820(B) may be connected to AR system 800 via a wireless connection (e.g., a BLUETOOTH connection). In still other embodiments, acoustic transducers 820(A) and 820(B) may not be used at all in conjunction with AR system 800.

Acoustic transducers 820 on frame 810 may be positioned in a variety of different ways, including along the length of the temples, across the bridge, above or below display devices 815(A) and 815(B), or some combination thereof. Acoustic transducers 820 may also be oriented such that the microphone array is able to detect sounds in a wide range of directions surrounding the user wearing the AR system 800. In some embodiments, an optimization process may be performed during manufacturing of AR system 800 to determine relative positioning of each acoustic transducer 820 in the microphone array.

In some examples, AR system 800 may include or be connected to an external device (e.g., a paired device), such as neckband 805. Neckband 805 generally represents any type or form of paired device. Thus, the following discussion of neckband 805 may also apply to various other paired devices, such as charging cases, smart watches, smart phones, wrist bands, other wearable devices, hand-held controllers, tablet computers, laptop computers, other external compute devices, etc.

As shown, neckband 805 may be coupled to eyewear device 802 via one or more connectors. The connectors may be wired or wireless and may include electrical and/or non-electrical (e.g., structural) components. In some cases, eyewear device 802 and neckband 805 may operate independently without any wired or wireless connection between them. While FIG. 8 illustrates the components of eyewear device 802 and neckband 805 in example locations on eyewear device 802 and neckband 805, the components may be located elsewhere and/or distributed differently on eyewear device 802 and/or neckband 805. In some embodiments, the components of eyewear device 802 and neckband 805 may be located on one or more additional peripheral devices paired with eyewear device 802, neckband 805, or some combination thereof.

Pairing external devices, such as neckband 805, with AR eyewear devices may enable the eyewear devices to achieve the form factor of a pair of glasses while still providing sufficient battery and computation power for expanded capabilities. Some or all of the battery power, computational resources, and/or additional features of AR system 800 may be provided by a paired device or shared between a paired device and an eyewear device, thus reducing the weight, heat profile, and form factor of the eyewear device overall while still retaining desired functionality. For example, neckband 805 may allow components that would otherwise be included on an eyewear device to be included in neckband 805 since users may tolerate a heavier weight load on their shoulders than they would tolerate on their heads. Neckband 805 may also have a larger surface area over which to diffuse and disperse heat to the ambient environment. Thus, neckband 805 may allow for greater battery and computation capacity than might otherwise have been possible on a stand-alone eyewear device. Since weight carried in neckband 805 may be less invasive to a user than weight carried in eyewear device 802, a user may tolerate wearing a lighter eyewear device and carrying or wearing the paired device for greater lengths of time than a user would tolerate wearing a heavy standalone eyewear device, thereby enabling users to more fully incorporate artificial-reality environments into their day-to-day activities.

Neckband 805 may be communicatively coupled with eyewear device 802 and/or to other devices. These other devices may provide certain functions (e.g., tracking, localizing, depth mapping, processing, storage, etc.) to AR system 800. In the embodiment of FIG. 8, neckband 805 may include two acoustic transducers (e.g., 820(I) and 820(J)) that are part of the microphone array (or potentially form their own microphone subarray). Neckband 805 may also include a controller 825 and a power source 835.

Acoustic transducers 820(I) and 820(J) of neckband 805 may be configured to detect sound and convert the detected sound into an electronic format (analog or digital). In the embodiment of FIG. 8, acoustic transducers 820(I) and 820(J) may be positioned on neckband 805, thereby increasing the distance between the neckband acoustic transducers 820(I) and 820(J) and other acoustic transducers 820 positioned on eyewear device 802. In some cases, increasing the distance between acoustic transducers 820 of the microphone array may improve the accuracy of beamforming performed via the microphone array. For example, if a sound is detected by acoustic transducers 820(C) and 820(D) and the distance between acoustic transducers 820(C) and 820(D) is greater than, e.g., the distance between acoustic transducers 820(D) and 820(E), the determined source location of the detected sound may be more accurate than if the sound had been detected by acoustic transducers 820(D) and 820(E).

Controller 825 of neckband 805 may process information generated by the sensors on neckband 805 and/or AR system 800. For example, controller 825 may process information from the microphone array that describes sounds detected by the microphone array. For each detected sound, controller 825 may perform a direction-of-arrival (DOA) estimation to estimate a direction from which the detected sound arrived at the microphone array. As the microphone array detects sounds, controller 825 may populate an audio data set with the information. In embodiments in which AR system 800 includes an inertial measurement unit, controller 825 may compute all inertial and spatial calculations from the IMU located on eyewear device 802. A connector may convey information between AR system 800 and neckband 805 and between AR system 800 and controller 825. The information may be in the form of optical data, electrical data, wireless data, or any other transmittable data form. Moving the processing of information generated by AR system 800 to neckband 805 may reduce weight and heat in eyewear device 802, making it more comfortable to the user.

Power source 835 in neckband 805 may provide power to eyewear device 802 and/or to neckband 805. Power source 835 may include, without limitation, lithium ion batteries, lithium-polymer batteries, primary lithium batteries, alkaline batteries, or any other form of power storage. In some cases, power source 835 may be a wired power source. Including power source 835 on neckband 805 instead of on eyewear device 802 may help better distribute the weight and heat generated by power source 835.

As noted, some artificial-reality systems may, instead of blending an artificial reality with actual reality, substantially replace one or more of a user's sensory perceptions of the real world with a virtual experience. One example of this type of system is a head-worn display system, such as VR system 900 in FIG. 9, that mostly or completely covers a user's field of view. VR system 900 may include a front rigid body 902 and a band 904 shaped to fit around a user's head. VR system 900 may also include output audio transducers 906(A) and 906(B). Furthermore, while not shown in FIG. 9, front rigid body 902 may include one or more electronic elements, including one or more electronic displays, one or more inertial measurement units (IMUs), one or more tracking emitters or detectors, and/or any other suitable device or system for creating an artificial-reality experience.

Artificial-reality systems may include a variety of types of visual feedback mechanisms. For example, display devices in AR system 800 and/or VR system 900 may include one or more liquid crystal displays (LCDs), light emitting diode (LED) displays, microLED displays, organic LED (OLED) displays, digital light project (DLP) micro-displays, liquid crystal on silicon (LCoS) micro-displays, and/or any other suitable type of display screen. These artificial-reality systems may include a single display screen for both eyes or may provide a display screen for each eye, which may allow for additional flexibility for varifocal adjustments or for correcting a user's refractive error. Some of these artificial-reality systems may also include optical subsystems having one or more lenses (e.g., concave or convex lenses, Fresnel lenses, adjustable liquid lenses, etc.) through which a user may view a display screen. These optical subsystems may serve a variety of purposes, including to collimate (e.g., make an object appear at a greater distance than its physical distance), to magnify (e.g., make an object appear larger than its actual size), and/or to relay (to, e.g., the viewer's eyes) light. These optical subsystems may be used in a non-pupil-forming architecture (such as a single lens configuration that directly collimates light but results in so-called pincushion distortion) and/or a pupil-forming architecture (such as a multi-lens configuration that produces so-called barrel distortion to nullify pincushion distortion).

In addition to or instead of using display screens, some of the artificial-reality systems described herein may include one or more projection systems. For example, display devices in AR system 800 and/or VR system 900 may include micro-LED projectors that project light (using, e.g., a waveguide) into display devices, such as clear combiner lenses that allow ambient light to pass through. The display devices may refract the projected light toward a user's pupil and may enable a user to simultaneously view both artificial-reality content and the real world. The display devices may accomplish this using any of a variety of different optical components, including waveguide components (e.g., holographic, planar, diffractive, polarized, and/or reflective waveguide elements), light-manipulation surfaces and elements (such as diffractive, reflective, and refractive elements and gratings), coupling elements, etc. Artificial-reality systems may also be configured with any other suitable type or form of image projection system, such as retinal projectors used in virtual retina displays.

The artificial-reality systems described herein may also include various types of computer vision components and subsystems. For example, AR system 800 and/or VR system 900 may include one or more optical sensors, such as two-dimensional (2D) or 3D cameras, structured light transmitters and detectors, time-of-flight depth sensors, single-beam or sweeping laser rangefinders, 3D LiDAR sensors, and/or any other suitable type or form of optical sensor. An artificial-reality system may process data from one or more of these sensors to identify a location of a user, to map the real world, to provide a user with context about real-world surroundings, and/or to perform a variety of other functions.

The artificial-reality systems described herein may also include one or more input and/or output audio transducers. Output audio transducers may include voice coil speakers, ribbon speakers, electrostatic speakers, piezoelectric speakers, bone conduction transducers, cartilage conduction transducers, tragus-vibration transducers, and/or any other suitable type or form of audio transducer. Similarly, input audio transducers may include condenser microphones, dynamic microphones, ribbon microphones, and/or any other type or form of input transducer. In some embodiments, a single transducer may be used for both audio input and audio output.

In some embodiments, the artificial-reality systems described herein may also include tactile (i.e., haptic) feedback systems, which may be incorporated into headwear, gloves, body suits, handheld controllers, environmental devices (e.g., chairs, floormats, etc.), and/or any other type of device or system. Haptic feedback systems may provide various types of cutaneous feedback, including vibration, force, traction, texture, and/or temperature. Haptic feedback systems may also provide various types of kinesthetic feedback, such as motion and compliance. Haptic feedback may be implemented using motors, piezoelectric actuators, fluidic systems, and/or a variety of other types of feedback mechanisms. Haptic feedback systems may be implemented independent of other artificial-reality devices, within other artificial-reality devices, and/or in conjunction with other artificial-reality devices.

By providing haptic sensations, audible content, and/or visual content, artificial-reality systems may create an entire virtual experience or enhance a user's real-world experience in a variety of contexts and environments. For instance, artificial-reality systems may assist or extend a user's perception, memory, or cognition within a particular environment. Some systems may enhance a user's interactions with other people in the real world or may enable more immersive interactions with other people in a virtual world. Artificial-reality systems may also be used for educational purposes (e.g., for teaching or training in schools, hospitals, government organizations, military organizations, business enterprises, etc.), entertainment purposes (e.g., for playing video games, listening to music, watching video content, etc.), and/or for accessibility purposes (e.g., as hearing aids, visual aids, etc.). The embodiments disclosed herein may enable or enhance a user's artificial-reality experience in one or more of these contexts and environments and/or in other contexts and environments.

The process parameters and sequence of the steps described and/or illustrated herein are given by way of example only and may be varied as desired. For example, while the steps illustrated and/or described herein may be shown or discussed in a particular order, these steps do not necessarily need to be performed in the order illustrated or discussed. The various exemplary methods described and/or illustrated herein may also omit one or more of the steps described or illustrated herein or include additional steps in addition to those disclosed.

The preceding description has been provided to enable others skilled in the art to best utilize various aspects of the exemplary embodiments disclosed herein. This exemplary description is not intended to be exhaustive or to be limited to any precise form disclosed. Many modifications and variations are possible without departing from the spirit and scope of the present disclosure. The embodiments disclosed herein should be considered in all respects illustrative and not restrictive. Reference should be made to any claims appended hereto and their equivalents in determining the scope of the present disclosure.

Unless otherwise noted, the terms “connected to” and “coupled to” (and their derivatives), as used in the specification and/or claims, are to be construed as permitting both direct and indirect (i.e., via other elements or components) connection. In addition, the terms “a” or “an,” as used in the specification and/or claims, are to be construed as meaning “at least one of.” Finally, for ease of use, the terms “including” and “having” (and their derivatives), as used in the specification and/or claims, are interchangeable with and have the same meaning as the word “comprising.”

What is claimed is:

1. A method comprising:
selectively depositing material over a layered structure of a light-emitting device; and
defining an emitter size of the light-emitting device by causing the material to disorder regions of a light-emitting layer included in the layered structure.

2. The method of claim 1, wherein causing the material to disorder the regions of the light-emitting layer comprises inducing impurity-free disordering of the material within the light-emitting layer via Group III element extraction at a temperature that exceeds a certain threshold.

3. The method of claim 1, wherein causing the material to disorder the regions of the light-emitting layer comprises causing impurity-induced disordering of the material within the light-emitting layer via at least one of:
ion implantation; or
atomic diffusion.

4. The method of claim 1, wherein defining the emitter size of the light-emitting device comprises defining the emitter size of the light-emitting device by applying at least one fabrication process to the layered structure outside the light-emitting layer.

5. The method of claim 4, wherein the fabrication process comprises at least one of:
etching;
band-gap tuning; or
impurity diffusion.

6. The method of claim 4, wherein the fabrication process comprises inducing elemental diffusion in the layered structure to widen a band gap of the light-emitting layer by:
increasing a temperature of the material; and
extracting an element from at least one layer included in the layered structure as a result of the increased temperature.

7. The method of claim 1, wherein the light-emitting layer is disposed between semiconductor layers included in the layered structure.

8. The method of claim 7, wherein defining the emitter size of the light-emitting device comprises tuning a band gap of at least one of the layers included in the layered structure via quantum-well intermixing (QWI).

9. The method of claim 7, wherein the light-emitting layer and the semiconductor layers are collectively sized at 50 microns or less.

10. The method of claim 1, wherein causing the material to disorder the regions of the light-emitting layer comprises at least one of:
inducing vertical disordering of the material within the light-emitting layer to achieve lateral carrier confinement in at least one layer included the layered structure; or
inducing lateral disordering of the material within the light-emitting layer to achieve lateral carrier confinement in at least one layer included the layered structure.

11. The method of claim 1, wherein the material comprises a dielectric.

12. The method of claim 1, wherein causing the material to disorder the regions of the light-emitting layer comprises sharpening a band-gap profile of an edge of at least one layer included in the layered structure.

13. The method of claim 1, further comprising:
removing semiconductor material from an edge of at least one layer included in the layered structure; and
causing the material to disorder the edge to reduce non-radiative losses.

14. The method of claim 1, further comprising:
causing selective area growth at an edge of at least one layer included in the layered structure; and
causing the material to disorder the edge to reduce non-radiative losses.

15. The method of claim 1, further comprising implementing the light-emitting device in an artificial-reality device dimensioned to be worn by a user.

16. A light-emitting device comprising:
a layered structure comprising a light-emitting layer disposed between semiconductor layers;
material selectively applied to the layered structure; and
an emitter whose size is defined by regions of the light-emitting layer that are disordered by the material.

17. The light-emitting device of claim 16, wherein the regions of the light-emitting layer are either vertically disordered or laterally disordered by the material.

18. The light-emitting device of claim 16, wherein the light-emitting layer is disposed between semiconductor layers included in the layered structure.

19. The light-emitting device of claim 16, wherein at least one of the layers included in the layered structure has a band gap that is tuned via quantum-well intermixing (QWI).

20. A system comprising:
an artificial-reality device dimensioned to be worn by a user; and
a light-emitting device incorporated in the artificial-reality device, the light-emitting device comprising:
a layered structure comprising a light-emitting layer disposed between semiconductor layers;
material selectively applied to the layered structure; and
an emitter whose size is defined by regions of the light-emitting layer that are disordered by the material.
